(19) United States
(12) Patent Application Publication
(10) Pub. No.: US 2024/0268205 A1
(43) Pub. Date: Aug. 8, 2024

(54) OLED STRUCTURE AND PROCESS BASED ON PIXEL PASSIVATION BY REMOVING OLED STACK OVER HEAT ABSORBENT STRUCTURES

(71) Applicant: Applied Materials, Inc., Santa Clara, CA (US)

(72) Inventors: Ji Young CHOUNG, Hwaseong-si (KR); Chung-chia CHEN, Hsinchu City (TW); Jungmin LEE, Santa Clara, CA (US); Yu-hsin LIN, Zhubei City (TW); Takuji KATO, Yokohama City (JP)

(21) Appl. No.: 18/431,001

(22) Filed: Feb. 2, 2024

Related U.S. Application Data
(60) Provisional application No. 63/483,123, filed on Feb. 3, 2023.

(51) Int. Cl. H10K 59/80; H10K 59/12; H10K 59/122

(52) U.S. Cl. CPC H10K 59/8794; H10K 59/1201; H10K 59/122; H10K 59/80521

(57) ABSTRACT

Devices with sub-pixel circuits and methods of forming sub-pixel circuits that may be utilized in a display such as an organic light-emitting diode (OLED) display. In one example, a device includes a substrate, a plurality of pixel-defining layer (PDL) structures disposed over the substrate, each PDL structure having an upper PDL surface, and a plurality of heat absorbent structures disposed on the upper PDL surface of the plurality PDL structures. Each adjacent heat absorbent structure includes a top surface and two sidewalls. Adjacent heat absorbent structures define sub-pixels of the device, each sub-pixel includes an anode, an OLED material disposed over the anode, a cathode disposed over the OLED material, and an encapsulation layer disposed over the cathode and over a first portion of the top surface of the first heat absorbent structure and a second portion of the top surface of the second heat absorbent structure.

### CROSS-REFERENCE TO RELATED APPLICATIONS

This application claims priority to U.S. Provisional Patent Application Ser. No. 63/483,123, filed on Feb. 3, 2023, which is herein incorporated by reference.

### BACKGROUND

### Field

Embodiments described herein generally relate to a display. More specifically, embodiments described herein relate to sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits that can increase the pixels-per-inch and provide improved OLED performance.

### SUMMARY

In one embodiment, a device is provided. The device includes a substrate, a plurality of pixel-defining layer (PDL) structures disposed over the substrate, each PDL structure has an upper PDL surface, and a plurality of heat absorbent structures disposed on the upper PDL surface of the plurality PDL structures. Each adjacent heat absorbent structure includes a top surface and two sidewalls. Adjacent heat absorbent structures define sub-pixels of the device, each sub-pixel includes an anode, an organic light emitting diode (OLED) material disposed over the anode, the OLED material having a first OLED endpoint contacting a first sidewall of a first heat absorbent structure and a second OLED endpoint contacting a second sidewall of a second heat absorbent structure, a cathode disposed over the OLED material, the cathode having a first cathode endpoint contacting the first sidewall of the first heat absorbent structure and a second cathode endpoint contacting the second sidewall of the second heat absorbent structure, and an encapsulation layer disposed over the cathode and over a first portion of the top surface of the first heat absorbent structure and a second portion of the top surface of the second heat absorbent structure.

In another embodiment, a device is provided. The device includes a substrate and a plurality of heat absorbent structures disposed over the substrate, each heat absorbent structure having a top surface and two sidewalls. A plurality of sub-pixels are defined by the heat absorbent structures, each sub-pixel includes an anode, an organic light-emitting diode (OLED) material disposed on the anode and extending along a first sidewall of a first heat absorbent structure and contacting the top surface of the first heat absorbent structure with a first OLED endpoint, and along a second sidewall of a second heat absorbent structure and contacting the top surface of the second heat absorbent structure with a second OLED endpoint, a cathode disposed over the OLED material and extending along the first sidewall of the first heat absorbent structure and contacting the top surface of the first heat absorbent structure with a first cathode endpoint and along the second sidewall of the second heat absorbent structure and contacting the top surface of the second heat absorbent structure with a second cathode endpoint, and an encapsulation layer disposed over the cathode and contacting a first portion of the top surface of the first heat absorbent structure and contacting a second portion of the top surface of the second heat absorbent structure.

In another embodiment, a method is provided. The method includes disposing a first OLED material in a first pixel opening over an anode, second pixel opening, and over a top surface of a plurality of adjacent heat absorbent structures disposed on an upper PDL surface of pixel-defining layer (PDL) structures, the first pixel opening and the second pixel opening are defined by adjacent heat absorbent structures of the plurality of adjacent heat absorbent structures, disposing a cathode over the first OLED material, removing the first OLED material and the cathode over the top surface of the plurality of adjacent heat absorbent structures, depositing an encapsulation layer over the cathode and over the top surface of the plurality of adjacent heat absorbent structures, forming a photoresist over the encapsulation layer in the first pixel opening and over a first portion of the top surface of a first heat absorbent structure and a second portion of the top surface of a second heat absorbent structure, and removing the encapsulation layer exposed by the photoresist.

In another embodiment, a method is provided. The method includes disposing a first OLED material in a first pixel opening over an anode, second pixel opening, and over a top surface of a plurality of adjacent heat absorbent structures disposed on an upper PDL surface of pixel-defining layer (PDL) structures, first pixel opening and the second pixel opening are defined by adjacent heat absorbent structures of the plurality of adjacent heat absorbent structures, removing the first OLED material over the top surface of the plurality of adjacent heat absorbent structures, disposing a cathode over the first OLED material and over the top surface of the plurality of adjacent heat absorbent structures, depositing an encapsulation layer over the cathode, forming a photoresist over the encapsulation layer in the first pixel opening and over a first portion of the top surface of a first heat absorbent structure and a second portion of the top surface of a second heat absorbent structure, and removing the encapsulation layer and cathode exposed by the photoresist and over the first portion of the top surface of the first heat absorbent structure and the second portion of the top surface of the second heat absorbent structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A is a schematic, cross-sectional view of a sub-pixel circuit according to embodiments.

FIG. 1B is a schematic, cross-sectional view of a sub-pixel circuit according to embodiments.

FIG. 1C is a top sectional view of a sub-pixel circuit according to embodiments.

FIG. 2 is a flow a flow diagram a method for forming a sub-pixel circuit according to embodiments.

FIGS. 3A-3E are schematic, cross-sectional views of a portion of a substrate during a method for forming a sub-pixel circuit according to embodiments.

FIG. 4 is a flow a flow diagram a method for forming a sub-pixel circuit according to embodiments.

FIGS. 5A-5E are schematic, cross-sectional views of a portion of a substrate during a method for forming OLED pixel structure according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display.

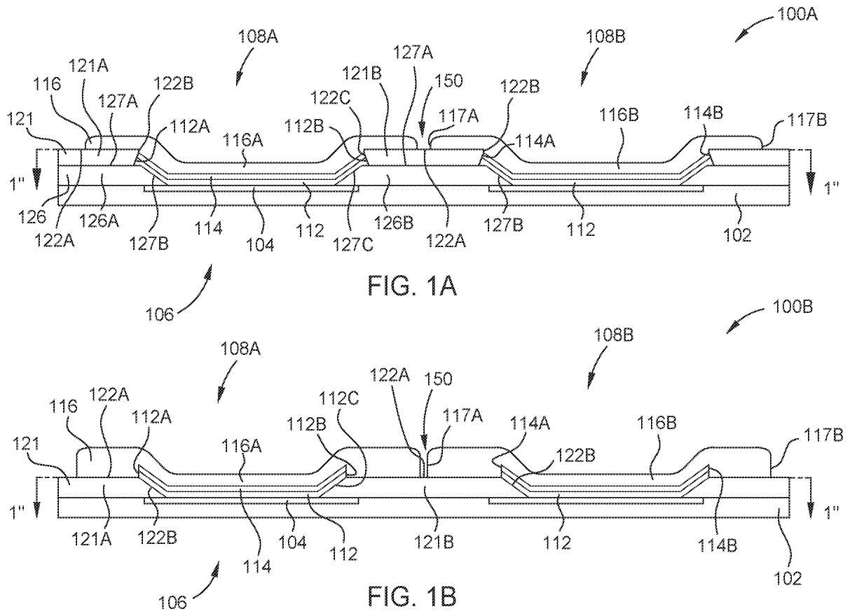

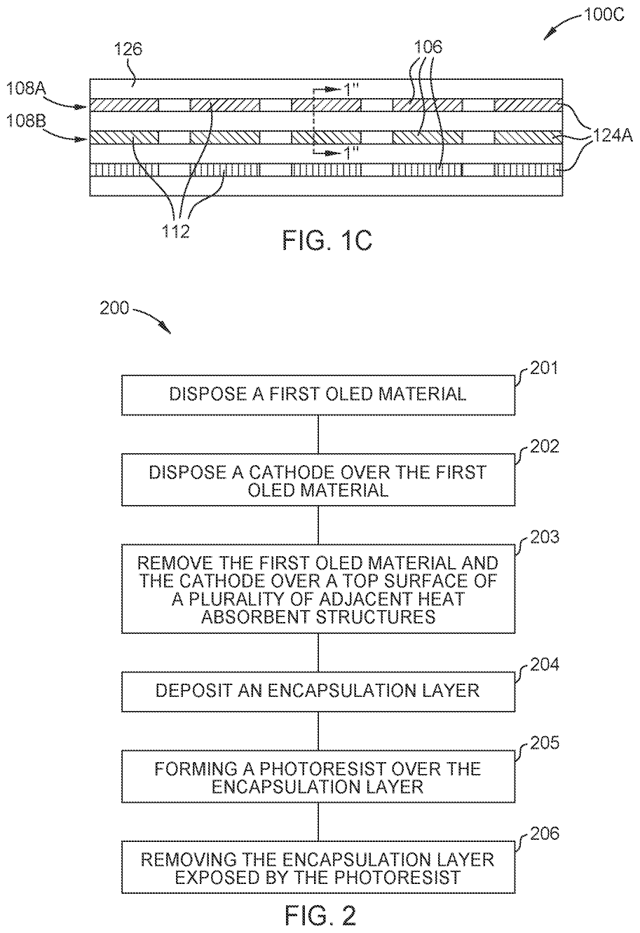

FIG. 1A is a schematic, cross-sectional view of a sub-pixel circuit 100A. The cross-sectional view of FIG. 1A is taken along section line 1″-1″ of FIG. 1C.

The sub-pixel circuit 100A includes a substrate 102. Metal-containing layers 104 may be patterned on the substrate 102 and are defined by adjacent pixel-defining layer (PDL) structures 126 disposed on the substrate 102. In one embodiment, the metal-containing layers 104 are pre-patterned on the substrate 102. E.g., the substrate 102 is a pre-patterned indium tin oxide (ITO) glass substrate. The metal-containing layers 104 are configured to operate as anodes of respective sub-pixels. The metal-containing layers 104 include, but are not limited to, chromium, titanium, gold, silver, copper, aluminum, ITO, a combination thereof, or other suitably conductive materials.

The PDL structures 126 are disposed over the substrate 102. The PDL structures include an upper PDL surface 127A coupled to a first PDL sidewall 127B and a second PDL sidewall 127C. The first PDL sidewall 127B and the second PDL sidewall 127C both have a tapered edge. The PDL structures 126 include one of an organic material, an organic material with an inorganic coating disposed thereover, or an inorganic material. The organic material of the PDL structures 126 includes, but is not limited to, polyimides. The inorganic material of the PDL structures 126 includes, but is not limited to, silicon oxide (SiO₂), silicon nitride (Si₃N₄), silicon oxynitride (Si₂N₂O), magnesium fluoride (MgF₂), or combinations thereof. Adjacent PDL structures 126 define a respective sub-pixel 106 and expose the anode (i.e., metal-containing layer 104) of the respective sub-pixel 106 of the sub-pixel circuit 100A.

The sub-pixel circuit 100A has adjacent heat absorbent structures 121 including a first heat absorbent structure 121A and a second heat absorbent structure 121B. The heat absorbent structures 121 are disposed on the upper PDL surface 127A of the PDL structures 126. The heat absorbent structures 121 include a top surface 122A coupled to a first sidewall 122B and a second sidewall 122C. Both the first sidewall 122B and the second sidewall 122C have an inversed tapered edge. The heat absorbent structures 121 absorb energy to generate heat. The generated heat is local to the heat absorbent structures 121. The localized heating of the heat absorbent structures 121 removes material disposed on the top surface 122A of the heat absorbent structures 121. The material may be an organic light-emitting diode (OLED) material 112, and in some embodiments a cathode 114. The material may be removed by evaporation. In some embodiments, the heat absorbent structure 121 includes a metal layer. The metal layer includes, but is not limited to, molybdenum or titanium. In some embodiments, the heat absorbent structure 121 includes a multi-layer structure. The multi-layer structure may include a metal layer, a transparent layer, and another metal layer. The metal layers include, but are not limited to, molybdenum or titanium. The transparent layer includes, but is not limited to, silicon oxide (SiO₂) or silicon nitrides (SiNₓ).

The sub-pixel circuit 100A includes at least a first sub-pixel 108A and a second sub-pixel 108B. While the Figures depict the first sub-pixel 108A and the second sub-pixel 108B, the sub-pixel circuit 100A of the embodiments described herein may include three or more sub-pixels 106, such as a third and fourth sub-pixel. Each sub-pixel 106 has the OLED material 112 configured to emit a white, red, green, blue or other color light when energized. E.g., the OLED material 112 of the first sub-pixel 108A emits a red light when energized, the OLED material 112 of the second sub-pixel 108B emits a green light when energized, the OLED material 112 of a third sub-pixel emits a blue light when energized, and the OLED material 112 of a fourth sub-pixel and a fifth sub-pixel emits another color light when energized. The OLED material 112 is different than the material of the PDL structures 126.

The OLED material 112 is disposed over the metal-containing layer 104. The OLED material 112 has a first OLED endpoint 112A of the OLED material 112 that contacts the first sidewall 122B of the first heat absorbent structure 121A. The OLED material 112 has a second OLED endpoint 112B that contacts the second sidewall 122C of the second heat absorbent structure 121B. The OLED material 112 is disposed over the PDL structures 126. The OLED material 112 is disposed over the first PDL sidewall 127B of the first PDL structure 126A over the upper PDL surface 127A of the first PDL structure 126A. In some embodiments, the OLED material 112 contacts the first PDL sidewall 127B and the upper PDL surface 127A of the first PDL structure 126A. The OLED material 112 is disposed over the second PDL sidewall 127C of the second PDL structure 126B over the upper PDL surface 127A of the second PDL structure 126B. In some embodiments, the OLED material 112 contacts the second PDL sidewall 127C and the upper PDL surface 127A of the second PDL structure 126B.

The cathode 114 is disposed over the OLED material 112. The cathode 114 includes a conductive material, such as a metal or metal alloy. E.g., the cathode 114 includes, but is not limited to, silver, magnesium, aluminum, ITO, or a combination thereof. The material of the cathode 114 is different from the material of the OLED material 112 and the PDL structures 126. The cathode 114 further includes a first cathode endpoint 114A that contacts the first sidewall 122B of the first heat absorbent structure 121A. The cathode 114 includes a second cathode endpoint 114B that contacts the second sidewall 122C of the second heat absorbent structure 121B. The cathode 114 is disposed over the PDL structures 126.

Each sub-pixel 106 includes an encapsulation layer 116. The sub-pixel circuit 100A includes a first encapsulation layer 116A of the first sub-pixel 108A. The sub-pixel circuit 100A further includes a second encapsulation layer 116B of the second sub-pixel 108B. The encapsulation layer 116 may be or may correspond to a local passivation layer. The encapsulation layer 116 of a respective sub-pixel is disposed over the cathode 114 (and OLED material 112). The encapsulation layer 116 includes a first encapsulation sidewall 117A and a second encapsulation sidewall 117B. The first encapsulation layer 116A contacts a first portion of the top surface 122A of the first heat absorbent structure 121A. The first encapsulation layer 116A also contacts a second portion of the top surface 122A of the second heat absorbent structure 121B. The second encapsulation layer 116B contacts a first portion of the top surface 122A of the second heat absorbent structure 121B. In some embodiments, a gap 150 exists between the first encapsulation layer 116A on the second portion of the top surface 122A of the second heat absorbent structure 121B and the second encapsulation layer 116B on the first portion of the top surface 122A of the second heat absorbent structure 121B. In some embodiments, the second encapsulation layer 116B overlaps the first encapsulation layer 116A on the top surface 122A of the second heat absorbent structure 121B.

The encapsulation layer 116 may have a thickness of between 0.1 μm and 2 μm. The encapsulation layer 116 includes a non-conductive inorganic material, such as a silicon-containing material. The silicon containing material may include Si₃N₄ containing materials. The material of the encapsulation layer 116 is different from the material of the cathode 114, the OLED material 112, and the PDL structures 126. In some embodiments, the sub-pixel circuit 100A further includes a global encapsulation layer (not shown) disposed over the encapsulation layer 116 and uncovered portions of the heat absorbent structures 121.

FIG. 1B is a schematic, cross-sectional view of a sub-pixel circuit 100B. The cross-sectional view of FIG. 1B is taken along section line 1″-1″ of FIG. 1C.

The sub-pixel circuit 100B includes the substrate 102. The metal-containing layers 104 may be patterned on the substrate 102 and are defined by the adjacent heat absorbent structures 121 disposed on the substrate 102. In one embodiment, the metal-containing layers 104 are pre-patterned on the substrate 102. E.g., the substrate 102 is a pre-patterned indium tin oxide (ITO) glass substrate. The metal-containing layers 104 are configured to operate as anodes of respective sub-pixels. The metal-containing layers 104 include, but are not limited to, chromium, titanium, gold, silver, copper, aluminum, ITO, a combination thereof, or other suitably conductive materials.

The heat absorbent structures 121 are disposed over the substrate 102. The heat absorbent structures 121 include the top surface 122A coupled to the first sidewall 122B and the second sidewall 122C. The first sidewall 122B and the second sidewall 122C both have a tapered edge. The heat absorbent structures 121 include one of an organic material, an organic material with an inorganic coating disposed thereover, or an inorganic material. The organic material of the heat absorbent structures 121 includes, but is not limited to, polyimides. The inorganic material of the heat absorbent structures 121 includes, but is not limited to, silicon oxide (SiO₂), silicon nitride (SisN₄), silicon oxynitride (Si₂N₂O), magnesium fluoride (MgF₂), or combinations thereof. In some embodiments, the heat absorbent structure 121 includes a metal layer. The metal layer includes, but is not limited to, molybdenum or titanium. In some embodiments, the heat absorbent structure 121 includes a multi-layer structure. The multi-layer structure may include a metal layer, a transparent layer, and another metal layer. The metal layers include, but are not limited to, molybdenum or titanium. The transparent layer includes, but is not limited to, silicon oxide (SiO₂) or silicon nitrides (SiNₓ).

Adjacent heat absorbent structures 121 define a respective sub-pixel 106 and expose the anode (i.e., metal-containing layer 104) of the respective sub-pixel 106 of the sub-pixel circuit 100B. In sub-pixel circuit 100B, the heat absorbent structures 121 act as the PDL structures 126 of sub-pixel circuit 100A. The heat absorbent structures 121 absorb energy to generate heat. The generated heat is local to the heat absorbent structures 121. The localized heating of the heat absorbent structures 121 removes material disposed on the top surface 122A of the heat absorbent structures 121. The material may be the OLED material 112, and in some embodiments the cathode 114. The material may be removed by evaporation.

The sub-pixel circuit 100B includes at least the first sub-pixel 108A and the second sub-pixel 108B. While the Figures depict the first sub-pixel 108A and the second sub-pixel 108B, the sub-pixel circuit 100B of the embodiments described herein may include three or more sub-pixels 106, such as a third and fourth sub-pixel. Each sub-pixel 106 has the organic light-emitting diode (OLED) material 112 configured to emit a white, red, green, blue or other color light when energized. E.g., the OLED material 112 of the first sub-pixel 108A emits a red light when energized, the OLED material 112 of the second sub-pixel 108B emits a green light when energized, the OLED material 112 of a third sub-pixel emits a blue light when energized, and the OLED material 112 of a fourth sub-pixel and a fifth sub-pixel emits another color light when energized. The OLED material 112 is different than the material of the heat absorbent structures 121.

The OLED material 112 is disposed over the metal-containing layer 104. The OLED material 112 is disposed along the first sidewall 122B of a first heat absorbent structure 121A. The OLED material 112 contacts the top surface 122A of the first heat absorbent structure 121A at a first OLED endpoint 112A. The OLED material 112 is disposed along a second sidewall 122C of a second heat absorbent structure 121B. The OLED material 112 contacts the top surface 122A of the second heat absorbent structure 121B at a second OLED endpoint 112B.

The cathode 114 is disposed over the OLED material 112. The cathode 114 includes a conductive material, such as a metal or metal alloy. E.g., the cathode 114 includes, but is not limited to, silver, magnesium, aluminum, ITO, or a combination thereof. The material of the cathode 114 is different from the material of the OLED material 112 and the heat absorbent structures 121. The cathode 114 is disposed along the first sidewall 122B of the first heat absorbent structure 121A and contacting the top surface 122A of the first heat absorbent structure 121A with a first cathode endpoint 114A. The cathode 114 is disposed along the second sidewall 122C of the second heat absorbent structure 121B and contacting the top surface 122A of the second heat absorbent structure 121B with a second cathode endpoint 114B.

Each sub-pixel 106 includes the encapsulation layer 116. The sub-pixel circuit 100B includes the first encapsulation layer 116A of the first sub-pixel 108A. The sub-pixel circuit 100B further includes the second encapsulation layer 116B of the second sub-pixel 108B. The encapsulation layer 116 may be or may correspond to a local passivation layer. The encapsulation layer 116 of a respective sub-pixel is disposed over the cathode 114 (and OLED material 112). The encapsulation layer 116 includes a first encapsulation sidewall 117A and a second encapsulation sidewall 117B. The first encapsulation layer 116A contacts a first portion of the top surface 122A of the first heat absorbent structure 121A. The first encapsulation layer 116A also contacts a second portion of the top surface 122A of the second heat absorbent structure 121B. The second encapsulation layer 116B contacts a first portion of the top surface 122A of the second heat absorbent structure 121B. In some embodiments, a gap 150 exists between the first encapsulation layer 116A on the second portion of the top surface 122A of the second heat absorbent structure 121B and the second encapsulation layer 116B on the first portion of the top surface 122A of the second heat absorbent structure 121B. The encapsulation layer 116 may have a thickness 0.1 μm, and 2 μm. In some embodiments, the second encapsulation layer 116B overlaps the first encapsulation layer 116A on the top surface 122A of the second heat absorbent structure 121B. In some embodiments, the sub-pixel circuit 100B further includes a global encapsulation layer (not shown) disposed over the encapsulation layer 116 and uncovered portions of the heat absorbent structures 121.

FIG. 1C is a schematic, cross-sectional view of the sub-pixel circuit 100A having a line-type architecture 100C. In other embodiments, the sub-pixel circuit 100A has a dot-type architecture (not shown). The top sectional views of FIG. 1C is taken along section line 1′-1′ of FIGS. 1A and 1B. The line-type architecture 100C includes a plurality of pixel openings 124A from adjacent PDL structures 126. Each of pixel openings 124A define each of the sub-pixels 106 of the line-type architecture.

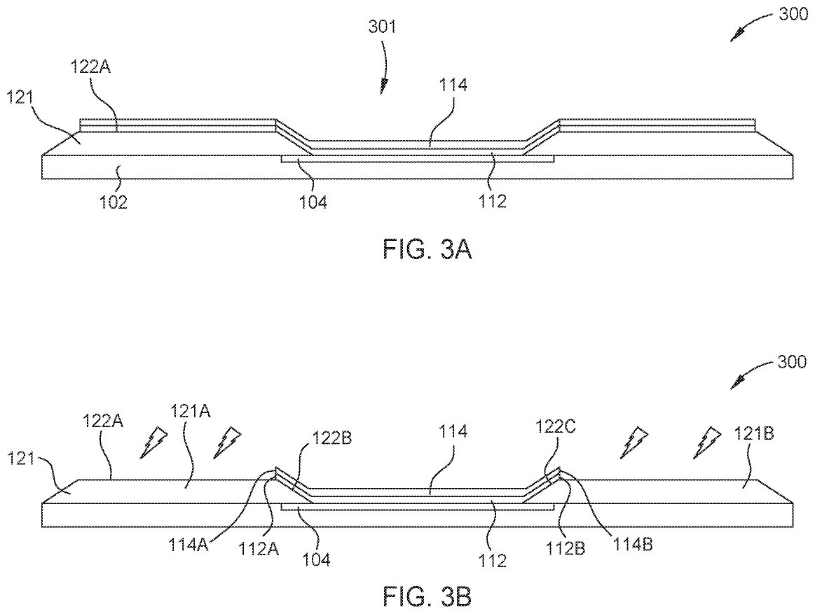

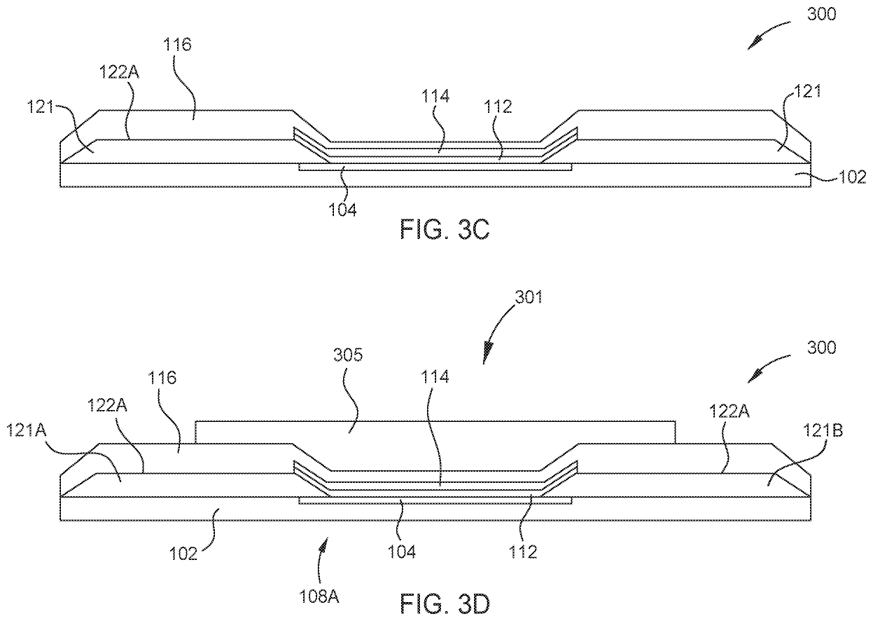

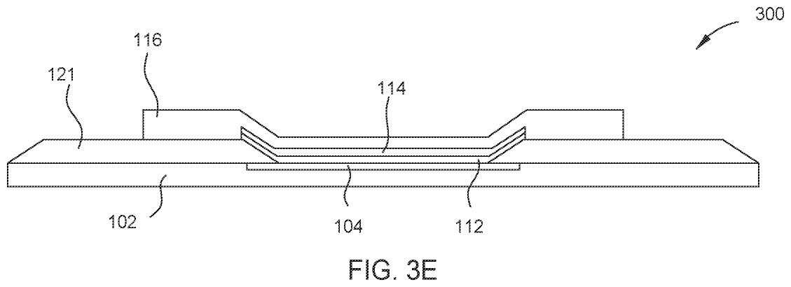

FIG. 2 is a flow a flow diagram a method 200 for forming a sub-pixel circuit according to embodiments. FIGS. 3A-3E are schematic, cross-sectional views of a portion of a substrate during the method 200 for forming a sub-pixel circuit 300 according to embodiments.

At operation 201, the first OLED material 112 is disposed. While FIG. 1A depict the first OLED material 112 as red, operations 201-206 and FIGS. 3A-3E describe the first OLED material 112 as green. The first OLED material 112 is disposed in a first pixel opening 301, a second pixel opening (not shown), and over a top surface 122A of a plurality of adjacent heat absorbent structures 121. The first pixel opening 301 and the second pixel opening are defined by adjacent heat absorbent structures of the plurality of adjacent heat absorbent structures 121. The adjacent heat absorbent structures 121 are disposed over the substrate 102, as shown in FIG. 1B. In other embodiments, the heat absorbent structures 121 are disposed on the PDL structures 126, as shown in FIG. 1A. The PDL structures are disposed over the substrate 102, as shown in FIG. 1A. The first OLED material 112 is disposed over the metal-containing layer 104.

At operation 202, a cathode 114 is disposed over the first OLED material 112. The cathode 114 is disposed in the first pixel opening 301, the second pixel opening, and over the top surface 122A of a plurality of adjacent heat absorbent structures 121. FIG. 3A depicts both operation 201 and operation 202.

At operation 203, the first OLED material 112 and the cathode 114 over the top surface 122A of the plurality of adjacent heat absorbent structures 121 are removed. The first OLED material 112 is removed by one or more of flash evaporation, joule heating, and laser. The flash evaporation, joule heating, or laser causes the heat absorbent structures 121 to absorb energy. The energy causes heat to be generated. The localized heating of the heat absorbent structures 121 removes the OLED material 112 and the cathode 114 disposed on the top surface 122A of the heat absorbent structures 121. The OLED material 112 and the cathode 114 may be removed by evaporation. When the OLED material 112 is removed from the top surface 122A, the first OLED endpoint 112A contacts the top surface 122A of the first heat absorbent structure 121A. The second OLED endpoint 112B contacts the top surface 122A of the second heat absorbent structure 121B. When the cathode 114 is removed from the top surface 122A, the first cathode endpoint 114A contacts the top surface 122A of the first heat absorbent structure 121A. The second cathode endpoint 114B contacts the top surface 122A of the second heat absorbent structure 121B. FIG. 3B depicts operation 203.

In embodiments with a PDL structure 126, when the OLED material 112 is removed from the top surface 122A, the first OLED endpoint 112A contacts the first sidewall 122B of the first heat absorbent structure 121A. The second OLED endpoint 112B contacts the second sidewall 122C of the second heat absorbent structure 121B. When the cathode 114 is removed from the top surface 122A, the first cathode endpoint 114A contacts the first sidewall 122B of the first heat absorbent structure 121A. The second cathode endpoint 114B contacts the second sidewall 122C of the second heat absorbent structure 121B.

At operation 204, an encapsulation layer 116 is deposited. The encapsulation layer 116 is deposited over the cathode 114. The encapsulation layer 116 is also deposited over the top surface 122A of the plurality of adjacent heat absorbent structures 121. FIG. 3C depicts operation 204.

At operation 205, a photoresist 305 is formed over the encapsulation layer 116. The photoresist 305 is formed over the encapsulation layer 116 in the first pixel opening 301. The photoresist 305 is also formed over a first portion of the top surface 122A of the first heat absorbent structure 121A. The photoresist 305 is also formed over a second portion of the top surface 122A of the second heat absorbent structure 121B. The photoresist 305 is a positive resist or a negative resist. A positive resist includes portions of the resist which, when exposed to electromagnetic radiation, are respectively soluble to a resist developer applied to the resist after the pattern is written into the resist using the electromagnetic radiation. A negative resist includes portions of the resist which, when exposed to electromagnetic radiation, are respectively insoluble to a resist developer applied to the resist after the pattern is written into the resist using the electromagnetic radiation. The chemical composition of photoresist 305 determines whether the resist is a positive resist or a negative resist. The patterning is one of a photolithography, digital lithography process, or laser ablation process. FIG. 3D depicts operation 205.

At operation 206, the encapsulation layer exposed by the photoresist 305 is removed. The encapsulation layer 116 can be removed by etching. The encapsulation layer 116 may be removed by dry etch process. FIG. 3E depicts operation 206.

Operations 201-206 are repeated for a second OLED material, such as a red OLED material or a blue OLED material. At operation 201, the second OLED material is disposed over the encapsulation layer 116 in the first pixel opening 301, in the second pixel opening, and over the top surface 122A of the adjacent heat absorbent structures 121.

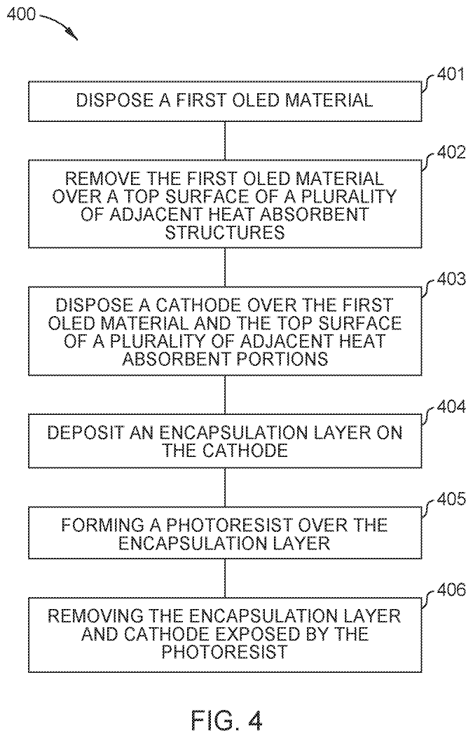

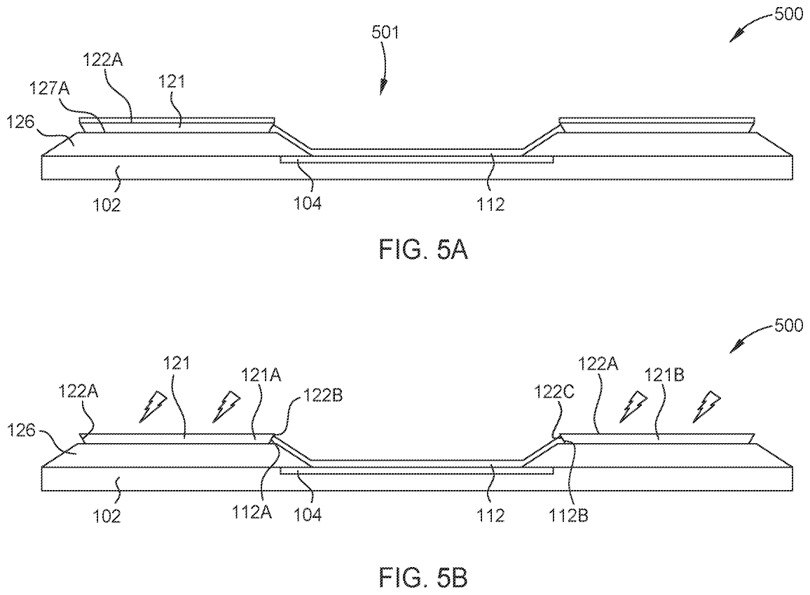

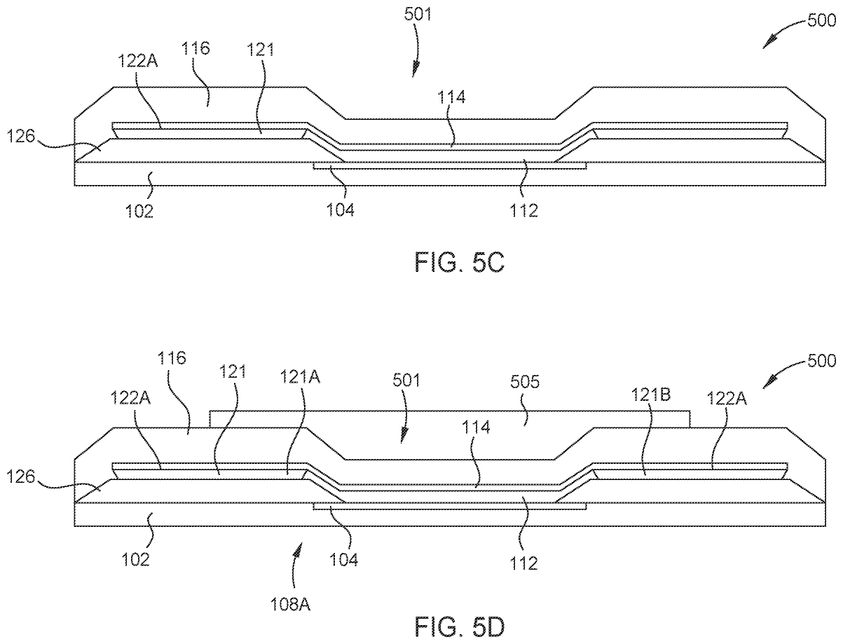

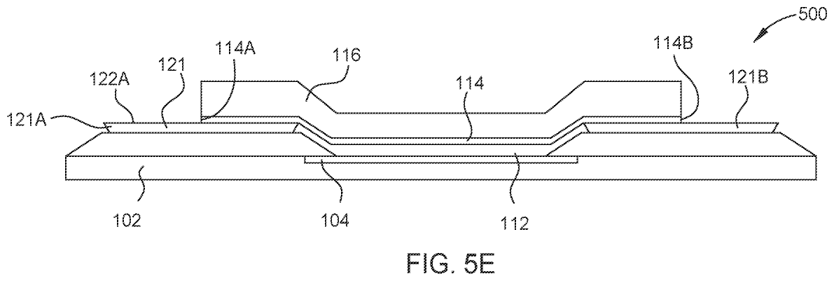

FIG. 4 is a flow a flow diagram a method 400 for forming a sub-pixel circuit according to embodiments. FIGS. 5A-5E are schematic, cross-sectional views of a portion of a substrate during a method 400 for forming OLED pixel structure 500 according to embodiments.

At operation 401, the first OLED material 112 is disposed. While FIG. 1A depict the first OLED material 112 as red, operations 401-406 and FIGS. 5A-5E describe the first OLED material 112 as green. The first OLED material 112 is disposed in a first pixel opening 501, a second pixel opening (not shown), and over a top surface 122A of a plurality of adjacent heat absorbent structures 121. The first pixel opening 501 and the second pixel opening are defined by adjacent heat absorbent structures of the plurality of adjacent heat absorbent structures 121. The adjacent heat absorbent structures 121 are disposed on the upper PDL surface 127A of the PDL structures 126. As shown in FIG. 1A the PDL structures are disposed over the substrate 102. In some embodiments, the adjacent heat absorbent structures 121 are disposed over the substrate 102 without PDL structures 126, as shown in FIG. 1B. The first OLED material 112 is disposed over the metal-containing layer 104. FIG. 5A depicts operation 401.

At operation 402, the first OLED material 112 over the top surface 122A of the plurality of adjacent heat absorbent structures 121 is removed. The first OLED material 112 is removed by one or more of flash evaporation, joule heating, and laser. The flash evaporation, joule heating, or laser causes the heat absorbent structure 121 to absorb energy. The energy causes heat to be generated. The localized heating of the heat absorbent structures 121 removes the OLED material 112 from the top surface 122A of the heat absorbent structures 121. The OLED material 112 may be removed by evaporation. When the OLED material 112 is removed from the top surface 122A, the first OLED endpoint 112A contacts the first sidewall 122B of the first heat absorbent structure 121A. The second OLED endpoint 112B contacts the second sidewall 122C of the second heat absorbent structure 121B. In embodiments without a PDL structure 126, when the OLED material 112 is removed from the top surface 122A, the first OLED endpoint 112A contacts the top surface 122A of the first heat absorbent structure 121A. The second OLED endpoint 112B contacts the top surface 122A of the second heat absorbent structure 121B. FIG. 5B depicts operation 402.

At operation 403, the cathode 114 is disposed. The cathode 114 is disposed in the first pixel opening 301, the second pixel opening, and over the top surface 122A of a plurality of adjacent heat absorbent structures 121.

At operation 404, the encapsulation layer 116 is deposited on the cathode 114. The encapsulation layer 116 is deposited in the first pixel opening 501 and the second pixel opening. The encapsulation layer 116 is also deposited over the top surface 122A of the plurality of adjacent heat absorbent structures 121. FIG. 5C depicts both operation 403 and operation 404.

At operation 405, a photoresist 505 is formed over the encapsulation layer 116. The photoresist 505 is formed over the encapsulation layer 116 in the first pixel opening 501. The photoresist 505 is also formed over a first portion of the top surface 122A of the first heat absorbent structure 121A. The photoresist 505 is also formed over a second portion of the top surface 122A of the second heat absorbent structure 121B. The photoresist 505 is a positive resist or a negative resist. A positive resist includes portions of the resist which, when exposed to electromagnetic radiation, are respectively soluble to a resist developer applied to the resist after the pattern is written into the resist using the electromagnetic radiation. A negative resist includes portions of the resist which, when exposed to electromagnetic radiation, are respectively insoluble to a resist developer applied to the resist after the pattern is written into the resist using the electromagnetic radiation. The chemical composition of photoresist 505 determines whether the resist is a positive resist or a negative resist. The photoresist 505 is patterned to form one of a pixel opening of the line-type architecture 100C of a first sub-pixel 108A. The patterning is one of a photolithography, digital lithography process, or laser ablation process. FIG. 5D depicts operation 405.

At operation 406, the encapsulation layer 116 and the cathode 114 exposed by the photoresist are removed. The encapsulation layer 116 and cathode 114 can be removed by etching. The encapsulation layer 116 and cathode 114 may be removed by dry etch process. When the cathode 114 is removed, the first cathode endpoint 114A extends over the first portion of the top surface 122A of a first heat absorbent structure 121A. The second cathode endpoint 114B extends the second portion of the top surface 122A of a second heat absorbent structure 121B. FIG. 5E depicts operation 406.

Operations 401-406 are repeated for a second OLED material, such a red OLED material or blue OLED material. At operation 401, the second OLED material is disposed over the encapsulation layer 116 in the first pixel opening 501, in the second pixel opening, and over the top surface 122A of the adjacent heat absorbent structures 121.

In summation, embodiments described herein generally relate to a display. More specifically, embodiments described herein relate to sub-pixel circuits that may be utilized in a display such as an OLED display.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a substrate;
a plurality of heat absorbent structures disposed over the substrate, each heat absorbent structure having:
a top surface;
two sidewalls;
a plurality of sub-pixels defined by the heat absorbent structures, each sub-pixel comprising:
an anode;
an organic light-emitting diode (OLED) material disposed on the anode and extending:
along a first sidewall of a first heat absorbent structure and contacting the top surface of the first heat absorbent structure with a first OLED endpoint; and
along a second sidewall of a second heat absorbent structure and contacting the top surface of the second heat absorbent structure with a second OLED endpoint;
a cathode disposed over the OLED material and extending:
along the first sidewall of the first heat absorbent structure and contacting the top surface of the first heat absorbent structure with a first cathode endpoint; and
along the second sidewall of the second heat absorbent structure and contacting the top surface of the second heat absorbent structure with a second cathode endpoint; and
an encapsulation layer disposed over the cathode and contacting a first portion of the top surface of the first heat absorbent structure and contacting a second portion of the top surface of the second heat absorbent structure.

2. The device of claim 1, wherein the two sidewalls of the plurality of heat absorbent structures have a tapered edge.

3. The device of claim 1, wherein the encapsulation layer of a first sub-pixel on the second portion of the top surface of the second heat absorbent structure and the encapsulation layer of a second sub-pixel on the first portion of the top surface of the second heat absorbent structure have a gap therebetween.

4. The device of claim 1, wherein the encapsulation layer of a second sub-pixel overlaps the encapsulation layer of a first sub-pixel on the top surface of the second heat absorbent structure.

5. The device of claim 1, wherein the cathode contacts the first portion of the top surface of the first heat absorbent structure and contacting the second portion of the surface of the second heat absorbent structure.

6. A device, comprising:
a substrate;
a plurality of pixel-defining layer (PDL) structures disposed over the substrate, each PDL structure has an upper PDL surface; and
a plurality of heat absorbent structures disposed on the upper PDL surface of the plurality PDL structures, each adjacent heat absorbent structure comprising:
a top surface; and
two sidewalls;
adjacent heat absorbent structures defining sub-pixels of the device, each sub-pixel comprising:
an anode;
an organic light emitting diode (OLED) material disposed over the anode, the OLED material having a first OLED endpoint contacting a first sidewall of a first heat absorbent structure and a second OLED endpoint contacting a second sidewall of a second heat absorbent structure;
a cathode disposed over the OLED material, the cathode having a first cathode endpoint contacting the first sidewall of the first heat absorbent structure and a second cathode endpoint contacting the second sidewall of the second heat absorbent structure; and
an encapsulation layer disposed over the cathode and over a first portion of the top surface of the first heat absorbent structure and a second portion of the top surface of the second heat absorbent structure.

7. The device of claim 6, wherein the encapsulation layer contacts the first portion of the top surface of the first heat absorbent structure and the second portion of the top surface of the second heat absorbent structure.

8. The device of claim 6, wherein the cathode contacts the first portion of the top surface of the first heat absorbent structure and the second portion of the top surface of the second heat absorbent structure.

9. The device of claim 6, wherein the two sidewalls of the plurality of heat absorbent structures have an inversed tapered edge.

10. The device of claim 6, wherein the encapsulation layer of a first sub-pixel on the second portion of the second heat absorbent structure and the encapsulation layer of a second sub-pixel on the first portion of the second heat absorbent structure have a gap therebetween.

11. The device of claim 6, wherein the encapsulation layer of a second sub-pixel overlaps the encapsulation layer of a first sub-pixel on the top surface of the second heat absorbent structure.

12. A method, comprising:
disposing a first OLED material in a first pixel opening over an anode, second pixel opening, and over a top surface of a plurality of adjacent heat absorbent structures disposed on a substrate, the first pixel opening and the second pixel opening are defined by adjacent heat absorbent structures of the plurality of adjacent heat absorbent structures;
disposing a cathode over the first OLED material;
removing the first OLED material and the cathode over the top surface of the plurality of adjacent heat absorbent structures;
depositing an encapsulation layer over the cathode and over the top surface of the plurality of adjacent heat absorbent structures;
forming a photoresist over the encapsulation layer in the first pixel opening and over a first portion of the top surface of a first heat absorbent structure and a second portion of the top surface of a second heat absorbent structure; and
removing the encapsulation layer exposed by the photoresist.

13. The method of claim 12, wherein the OLED material has a first OLED endpoint contacting a top surface of the first heat absorbent structure and a second OLED endpoint contacting a top surface of the second heat absorbent structure.

14. The method of claim 12, wherein the cathode has a first cathode endpoint contacting a top surface of the first heat absorbent structure and a second cathode endpoint contacting a top surface of the second heat absorbent structure.

15. The method of claim 12, wherein the heat absorbent structures absorb energy to generate heat causing the first OLED material and cathode to be removed over the top surface of the heat absorbent structures.

16. The method of claim 15, wherein the heat absorbent structures absorb energy from a flash evaporation process and the first OLED material and cathode are removed through evaporation.

17. A method, comprising:
disposing a first OLED material in a first pixel opening over an anode, second pixel opening, and over a top surface of a plurality of adjacent heat absorbent structures disposed on a substrate, first pixel opening and the second pixel opening are defined by adjacent heat absorbent structures of the plurality of adjacent heat absorbent structures;
removing the first OLED material over the top surface of the plurality of adjacent heat absorbent structures;
disposing a cathode over the first OLED material and over the top surface of the plurality of adjacent heat absorbent structures;
depositing an encapsulation layer over the cathode;
forming a photoresist over the encapsulation layer in the first pixel opening and over a first portion of the top surface of a first heat absorbent structure and a second portion of the top surface of a second heat absorbent structure; and
removing the encapsulation layer and cathode exposed by the photoresist and over the first portion of the top surface of the first heat absorbent structure and the second portion of the top surface of the second heat absorbent structure.

18. The method of claim 17, wherein the OLED material has a first OLED endpoint contacting a top surface of the first heat absorbent structure and a second OLED endpoint contacting a top surface of the second heat absorbent structure.

19. The method of claim 17, wherein the cathode has a first cathode endpoint over the first portion of the top surface of the first heat absorbent structure and a second cathode endpoint over the second portion of the top surface of the second heat absorbent structure.

20. The method of claim 17, wherein the heat absorbent structures absorb energy to generate heat causing the first OLED material to be removed over the top surface of the heat absorbent structures.
